(19) United States
(12) Patent Application Publication
(10) Pub. No.: US 2013/0115366 A1
(43) Pub. Date: May 9, 2013

(54) APPARATUS AND METHOD FOR FORMING THIN FILM

(71) Applicant: SAMSUNG DISPLAY CO., LTD., Gongin-City (KR)

(72) Inventors: Chang-Mo PARK, Seoul (KR); Jin-Koo CHUNG, Suwon-si (KR); Joo-Hyeon LEE, Yongin-si (KR)

(73) Assignee: SAMSUNG DISPLAY CO., LTD., Yongin-City (KR)

(21) Appl. No.: 13/726,504

(22) Filed: Dec. 24, 2012

Related U.S. Application Data
(62) Division of application No. 11/937,237, filed on Nov. 8, 2007, now abandoned.

(30) Foreign Application Priority Data
Nov. 21, 2006 (KR) 10-2006-0115313

(51) Int. Cl. B05D 3/04; C23C 14/54

(52) U.S. Cl. 427/9

(57) ABSTRACT

Apparatus and a method for forming a thin film including a vacuum chamber, a substrate holder located on the inner upper side of the vacuum chamber to secure a substrate, an evaporation source located on the inner lower side of the vacuum chamber to evaporate a deposition material, an evaporation source shutter substantially confining the deposition material evaporated to the evaporation source, a sensor located within the vacuum chamber to detect the thickness of the deposition material deposited on itself, and a calculation portion calculating the thickness of the deposition material deposited on the evaporation source shutter using data detected by the sensor.

### CROSS-REFERENCE TO RELATED APPLICATIONS

This is a divisional application of U.S. patent application Ser. No. 11/937,237, filed Nov. 8, 2007, which application claims priority to, and the benefit of, Korean Patent Application No. 10-2006-0115313, filed on Nov. 21, 2006, the disclosures of each of which are hereby incorporated herein by reference in their entireties for all purposes.

### BACKGROUND OF THE INVENTION

1. Field of the Invention

The present invention relates to an apparatus and method for forming a thin film which can accurately estimate deposition completion time and replacement time of an evaporation source by monitoring in real time the thickness of the thin film deposited on a substrate and the amount of a deposition material remaining in the evaporation source.

2. Description of Related Art

During the process of manufacturing a flat panel display device such as a liquid crystal display (“LCD”), an organic light emitting diode (“OLED”), etc., various thin films are formed on an insulating substrate such as glass. Unlike the process of manufacturing an LCD, the process of manufacturing an OLED thin film involves evaporating an organic material and depositing the evaporated organic material on the substrate.

The apparatus for forming a thin film includes a vacuum chamber, a substrate holder located within the vacuum chamber to hold the substrate, and an evaporation source located under the substrate holder to evaporate the material to be deposited on the substrate. The evaporation source includes an evaporation source shutter that closes an outlet of the evaporation source during the preheating process or during the process of preparing a substrate to prevent the deposition material from being diffused into the vacuum chamber. The evaporation source shutter opens the outlet of the evaporation source during the process of depositing a thin film on the substrate to diffuse the deposition material into the vacuum chamber to be formed on the substrate.

The amount of deposition material filled in the evaporation source is limited and is consumed by repetitive use. Accordingly, when the amount of the deposition material remaining in the evaporation source is not enough to process one substrate, a new evaporation source should be substituted. If the deposition material is exhausted while processing the substrate, the substrate under processing must be regarded as a failure.

During the process of closing the outlet of the evaporation source, the deposition material is continuously deposited in the evaporation source shutter. If the deposition material is excessively deposited in the evaporation source shutter, the deposition material contaminates the inside of the evaporation source and the periphery thereof. Accordingly, if an excess amount of deposition material is deposited in the evaporation source shutter it is necessary to remove the deposition material.

In this way, the apparatus is periodically required to be repaired by replacing the evaporation source or cleaning the evaporation source shutter. Further, there may not be enough deposition material remaining to complete the thin film deposition process or the evaporation source may be contaminated by the deposition material deposited in the evaporation source shutter.

### BRIEF SUMMARY OF THE INVENTION

The present invention provides an apparatus and method for forming a thin film which can monitor in real time the remaining amount and state of deposition material in an evaporation source.

According to one aspect, the present invention provides an apparatus for forming a thin film including: a vacuum chamber; a substrate holder located on the inner upper side of the vacuum chamber to hold a substrate; an evaporation source located on the inner lower side of the vacuum chamber to evaporate the deposition material; an evaporation source shutter shutting-off the deposition material evaporated in the evaporation source; a sensor located within the vacuum chamber to detect the thickness of the deposition material deposited on itself; and a calculation portion calculating the thickness of the deposition material deposited on the evaporation source shutter using data detected by the sensor.

Preferably, the sensor is mounted on the sidewall of the vacuum chamber in order not to disturb the deposition material being diffused toward the substrate.

Suitably, the calculation portion calculates at least one of the thickness of the deposition material deposited on the substrate and the thickness of the deposition material deposited on the evaporation source shutter from the thickness of the deposition material deposited on the sensor using a conversion factor.

The conversion factor is determined by the distance from the evaporation source and the evaporation rate of the deposition material evaporated in the evaporation source.

Moreover, the apparatus of the present invention further includes an alarm means connected to the calculation portion and generating an alarm if the amount of the deposition material remaining in the evaporation source is less than a predetermined amount in order to accurately maintain the operation of the apparatus.

The evaporation source shutter includes a shutter plate closing an outlet of the evaporation source and a shutter driving means driving the shutter plate.

The shutter plate advantageously includes a deposition material guide portion guiding the evaporated deposition material toward the sensor.

The deposition material guide portion includes a guide hole formed on an edge portion of the sensor of the shutter plate and further includes a guide pipe connected to the guide hole and extending toward the sensor.

The apparatus of the present invention further includes a thickness measuring means measuring the thickness of the deposition material deposited on the shutter plate.

The thickness measuring means includes an optical measuring means such as an ellipsometer located on the lower side of the vacuum chamber for measuring the thickness of the deposition material using light.

The shutter driving means may be a pneumatic cylinder driving the shutter plate using pneumatic pressure, while the thickness measuring means may measure the opening time of the shutter plate and calculate the thickness of the deposition material deposited on the shutter plate using the measured time.

The shutter driving means may be a servo motor, and the thickness measuring means may measure the torque necessary for the servo motor to open the shutter plate and calculate the thickness of the deposition material deposited on the shutter plate using the measured torque.

In another aspect, the present invention provides a method for forming a thin film, comprising: mounting a substrate on a substrate holder; forming a thin film on the substrate by evaporating deposition material from an evaporation source; detecting the evaporated amount of the deposition material; and calculating at least one of the thickness of the thin film formed on the substrate, the amount of the deposition material remaining in the evaporation source, and the thickness of the thin film formed on an evaporation source shutter based on the evaporated amount detected.

Preferably, the process of forming the thin film on the substrate by evaporating the deposition material of the evaporation source includes: maintaining the temperature of the deposition material at a preheating temperature by preheating the evaporation source while an outlet of the evaporation source is closed by the evaporation source shutter; evaporating the deposition material while maintaining the evaporation temperature by heating the evaporation source; and depositing the deposition material on the substrate by opening the evaporation source shutter.

Suitably, the process of the maintaining the temperature of the deposition material at a preheating temperature by preheating the evaporation source while the outlet of the evaporation source is closed and monitoring the amount of the deposition material evaporated.

Preferably, the method of the present invention includes lowering the temperature of the evaporation source if the amount of the detected deposition material exceeds a predetermined value in order to prevent waste of the deposition material.

The calculating process advantageously includes: deriving a conversion factor from at least one of the thickness of the deposition material deposited on the substrate, the amount of the deposition material remaining in the evaporation source, and the thickness of the thin film formed on the evaporation source shutter and using the detected data on the evaporation amount and the conversion factor to calculate at least one of the thickness of the deposition material deposited on the substrate, the amount of the deposition material remaining in the evaporation source, and the thickness of the thin film formed on the evaporation source shutter.

The conversion factor is preferably created by considering the distance from the evaporation source and the evaporation rate of the deposition material in the evaporation source.

The method of the present invention advantageously includes generating a deposition stop signal if the calculated value on the thickness of the deposition material deposited on the substrate exceeds a predetermined value.

The method of the present invention further includes generating an evaporation source replacement signal if the calculated value on the amount of the deposition material remaining in the evaporation source is less than a predetermined value.

The method of the present invention includes measuring the thickness of the deposition material deposited on the evaporation source shutter.

The process of measuring the thickness of the deposition material deposited on the evaporation source shutter either by irradiating light on the deposition material, by measuring the speed of the evaporation source shutter while applying constant force thereto, or by measuring the torque necessary for moving the evaporation source shutter.

The method of the present invention further includes generating a signal when the thickness of the deposition material deposited on the evaporation source shutter exceeds a predetermined value.

### BRIEF DESCRIPTION OF THE DRAWINGS

The features of the present invention will become more apparent to those of ordinary skill in the art by describing in detail exemplary embodiments thereof with reference to the attached drawings, in which:

FIG. 1 is a cross-sectional view showing a structure of an apparatus for forming a thin film in accordance with an exemplary embodiment of the present invention;

FIG. 2 is a cross-sectional view showing a structure of an evaporation source and an evaporation source shutter in accordance with the exemplary embodiment of the present invention;

FIG. 3 is a perspective view showing a state where a deposition material is formed on a shutter plate in accordance with the exemplary embodiment of the present invention;

FIG. 4 is a partially cross-sectional view showing a structure of thickness measuring means in accordance with the exemplary embodiment of the present invention; and

FIG. 5 is a graph showing the amount of a deposition material deposited in a sensor with respect to time in accordance with the exemplary embodiment of the present invention.

Use of the same reference symbols in different figures indicates similar or identical items.

### DETAILED DESCRIPTION

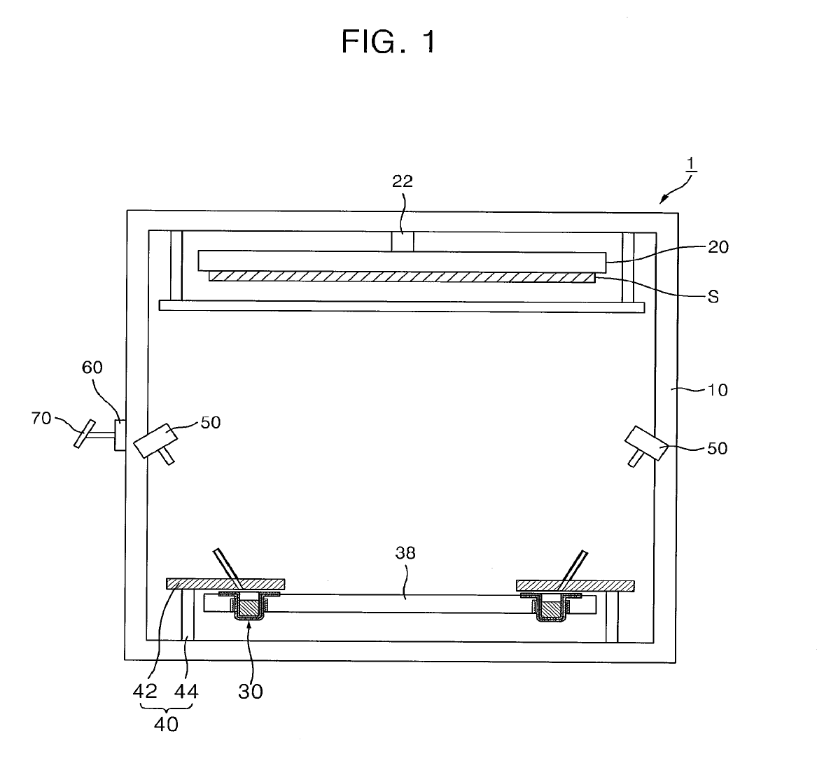

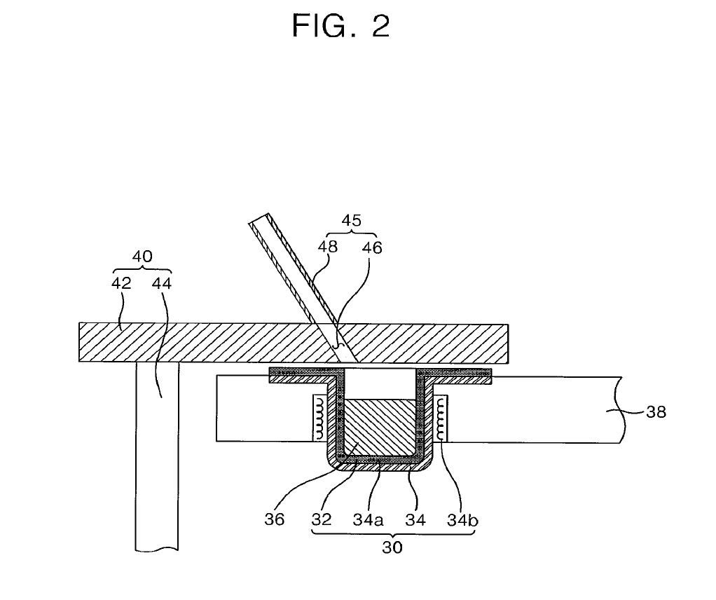

An apparatus for forming a thin film in accordance with an exemplary embodiment of the present invention will be described with reference to FIGS. 1 and 2. FIG. 1 is a cross-sectional view showing the structure of the apparatus for forming a thin film in accordance with an exemplary embodiment of the present invention and FIG. 2 is a cross-sectional view showing the structure of an evaporation source and an evaporation source shutter in accordance with the exemplary embodiment of the present invention.

As shown in FIG. 1, the apparatus for forming a thin film 1 includes a vacuum chamber 10, a substrate holder 20, an evaporation source 30, an evaporation source shutter 40, a sensor 50, and a calculation portion 60.

The vacuum chamber 10 has a cubic shape which can isolate the internal space thereof from the outside so as to maintain a vacuum state. The vacuum chamber 10 may have various shapes corresponding to the shape of a substrate S being processed. For example, if the substrate S has a circular shape, the vacuum chamber has a cylindrical shape, whereas, if the substrate S has a rectangular shape, the vacuum chamber has a rectangular shape. The vacuum chamber 10 further includes a vacuum pump (not shown) which exhausts gas to the outside of the vacuum chamber to lower the pressure within the vacuum chamber and a venting means (not shown) which supplies a predetermined gas into the vacuum chamber 10 to increase the pressure within the vacuum chamber 10.

As shown in FIG. 1, the substrate holder 20 is located on the inner upper portion of the vacuum chamber 10. Alternatively, the substrate holder 20 may be located on the sidewall of the vacuum chamber 10. The substrate S to be processed is held in the substrate holder 20. The substrate holder 20 stably holds the substrate S while the thin film is formed on the substrate S. Since the substrate S should be separated from the substrate holder 20 to be transferred to the outside after completing the process, the substrate holder 20 has a structure to easily mount and separate the substrate S. For example, the substrate S has a structure such as a clamp for clamping the lateral portion of the substrate S. The space between the clamp and the substrate S is expanded to prevent the center of the substrate S from hanging down.

The substrate holder 20 may also have a structure that can rotate the substrate S held by the substrate holder 20 in a horizontal direction. If the thin film is formed in a state where the substrate S is fixed in a certain position, the thin film may not be formed with a uniform thickness over the entire surface of the substrate S according to the diffusion degree of the deposition material. To this end, the substrate S is rotated while forming the thin film. For this purpose, the present invention has a structure that the substrate holder 20 may pivot on a center axis 22 of the substrate holder 20.

The evaporation source 30 is an element containing a constant amount of a deposition material 36 and evaporates the deposition material 36 at a constant rate. In this exemplary embodiment of the present invention, as shown in FIG. 1, the evaporation source 30 is located on the inner lower side of the vacuum chamber 10 opposite to the substrate holder 20. Therefore, the deposition material 36 evaporated in the evaporation source 30 is diffused upward and is thus deposited on the substrate S.

In order to evaporate the deposition material 36 at a constant rate, the evaporation source 30 containing the deposition material 36 includes a melting pot 32 and a heating device 34 as shown in FIG. 2. The melting pot 32 is a vessel that may contain a constant amount of the deposition material 36. Accordingly, the melting pot 32 is made of a chemically stable material which does not react with the deposition material 36. Moreover, the melting pot 32 may be made of a thermally stable material which can endure heat delivered from the heating device 34. The melting pot 32 has a projection to be held by an outlet of the heating device 34.

The heating device 34 heats the melting pot 32 to evaporate the deposition material 36 contained in the melting pot 32. Accordingly, the heating device 34 has an insertion hole 34a into which the melting pot 32 may be inserted, and electric heating wires 34b heating the melting pot 32 are formed within the insertion hole 34a. Accordingly, heat is applied to the melting pot 32 through the electric heating wires 34b.

Meanwhile, a single or a plurality of the evaporation sources 30 having the above-described structure may be provided in the apparatus of forming a thin film 1. If the single evaporation source 30 is provided, the evaporation source is located at the center of the vacuum chamber 10.

However, if the plurality of evaporation sources 30 is provided as shown in FIG. 1, an evaporation source mounting plate 38 is provided in the apparatus for forming a thin film to mount the plural evaporation sources 30, and a mounting portion (not shown) is provided on the evaporation source mounting plate 38. Furthermore, the evaporation source mounting plate 38 may be rotated.

Meanwhile, if the plural evaporation sources 30 are provided, it is advantageous that another evaporation source may be used after the exhaustion of the deposition material filled in one evaporation source. The evaporation source exhausting the deposition material is separated to refill the deposition material and then mounted again.

The evaporation source shutter 40 is an element preventing the outflow of the deposition material 36 evaporated in the evaporation source 30. In the apparatus of forming a thin film 1 according to this embodiment, the deposition material 36 in a vapor state generated by evaporating the deposition material 36 contained in the evaporation source 30 is deposited on the substrate S. Accordingly, in order to reduce the processing time, a process of forming the thin film is performed if the deposition material 36 is sufficiently evaporated by heating the evaporation source 30 before the process of forming the deposition material 36 on the substrate S. The evaporation source shutter 40 closes the outlet of the evaporation source 30 in the preheating process or in the process of preventing additional deposition of the deposition material 36 after the thin film is formed with a desired thickness on the substrate S.

Accordingly, the evaporation source shutter 40 according to this embodiment includes a shutter plate 42 and a shutter driving means 44, as shown in FIGS. 1 and 2. The shutter plate 42 is an element closing the outlet of the evaporation source 30, and has an area that can close the outlet of the evaporation source 30. The shutter plate 42 is preferably made of a material on which the deposition material 36 is not readily deposited.

The shutter driving means 44 is an element opening and closing the shutter plate 42. Accordingly, the shutter driving means 44 is connected to one side of the shutter plate 42 to rotate the shutter plate 42, as shown in FIG. 2. With the rotation, the shutter plate 42 opens and closes the outlet of the evaporation source 30.

Moreover, it is preferable that a deposition material guide portion 45 guiding the deposition material 36 evaporated in a direction toward the sensor 50 be further included in the shutter plate 42, as shown in FIG. 2. The deposition material guide portion 45 guides a very small amount of the deposition material 36 evaporated in the evaporation source 30 toward the sensor 50. Since the preheating temperature of the deposition material does not exceed the vaporization temperature, the deposition material is not evaporated during preheating except for a very small amount due to various reasons. Accordingly, the deposition material guide portion 45 guides the evaporated deposition material in a direction toward the sensor 50 so that the sensor 50 may detect any evaporated deposition material.

In this embodiment, The deposition material guide portion includes a guide hole 46 formed on an edge portion of the shutter plate 42, and a guide pipe 48 connected to the guide hole 46 and extending toward the sensor 50. Although the guide hole 46 may be formed by penetrating the shutter plate 42 in the vertical direction, the guide hole 46 may be preferably formed in an inclined direction toward the sensor 50. The guide pipe 48 is also attached to the shutter plate 42 in an inclined direction toward the sensor 50. It is preferable that the guide pipe 48 be formed long enough to be close to the sensor 50 to the extent that it does not disturb the operation of the shutter plate 42.

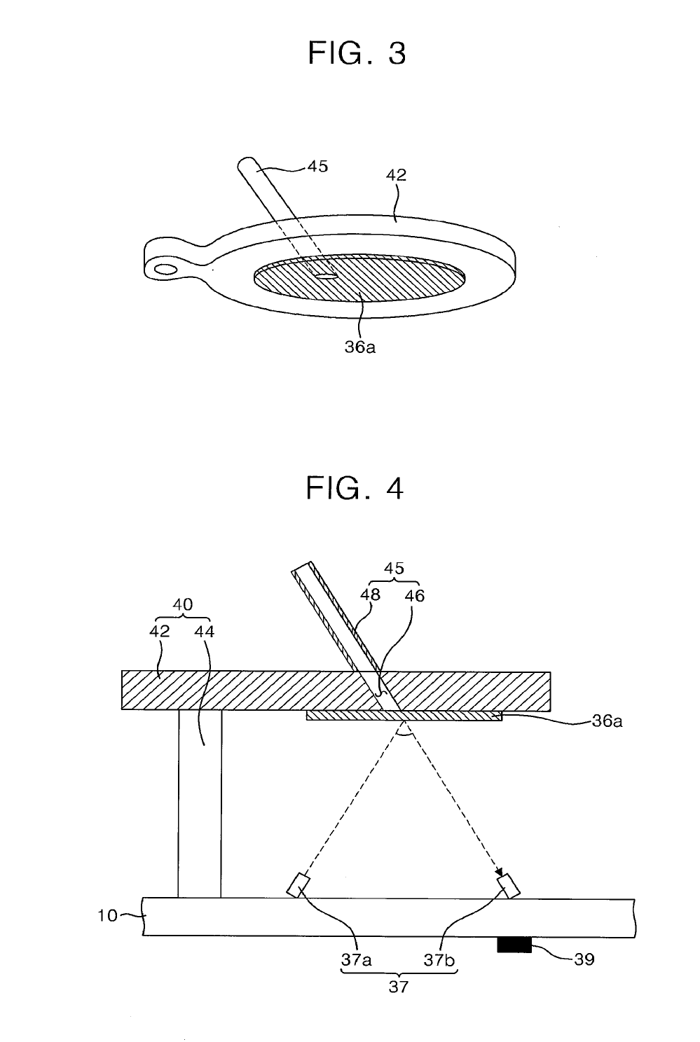

The apparatus 1 for forming a thin film according to this embodiment further includes a thickness measuring means. The thickness measuring means measures the thickness of a deposition material 36a deposited on the lower surface of the shutter plate 42, as illustrated in FIG. 3, while the evaporation source 30 is covered. If the thus deposited deposition material 36a is too thick, a portion of the deposition material may be separated to contaminate the evaporation source 30. Accordingly, it is desirable to measure in real time the thickness of the material 36a deposited on the lower surface of the shutter plate 42 and to carry out a process of removing the deposition material 36a on the lower surface of the shutter plate 42, if it exceeds a predetermined level. In other words, the shutter plate 42 is cleaned in advance before the evaporation source 30 is contaminated, thus preventing the contamination.

In order to carry out such a function in this embodiment, the thickness measuring means 37 includes an optical measuring means, located on the inner lower side of the vacuum chamber 10, for measuring the thickness of the deposition material using light, as shown in FIG. 4. Accordingly, the optical measuring means includes a light generating portion 37a generating and irradiating light to the shutter plate 42 and a light receiving portion 37b receiving the light reflected from the shutter plate 42. In particular, the optical measuring means is preferably an ellipsometer which measures the thickness using amplitude and phase difference of reflected laser. The ellipsometer has an advantage in that it is possible to accurately measure the thickness of the thin film.

The shutter driving means 44 may include a pneumatic cylinder driving the shutter plate 42 using pneumatic pressure. The thickness measuring means 37 may include a calculation means which measures the opening time of the shutter plate 42 and calculates the thickness of the deposition material 36a deposited on the shutter plate 42 using the measured time. The amount of the deposition material 36a deposited on the shutter plate 42 is determined by the time difference in opening the shutter with the same applied force when the shutter plate 42 is clean and after the vacuum chamber has been used to evaporate material. In general, if the same force is applied, the opening time is lengthened by the increase in weight of the shutter plate 42 due to the deposited material 36.

The shutter driving means 44 may include a servo motor, The thickness measuring means 37 may include a calculating means which measures torque necessary for the servo motor to open the shutter plate 42 and calculates the thickness of the deposition material 36a deposited on the shutter plate 42 using the torque. Since the servo motor can be very precisely controlled in general, the weight of the shutter plate 42 is estimated based on the torque necessary for the servo motor to open the shutter plate 42 so as to indirectly obtain the thickness of the deposition 36a deposited on the shutter plate 42 using the estimated weight.

It is desirable that the apparatus 1 for forming a thin film according to this embodiment further includes an auxiliary alarm means 39 which generates an alarm when the thickness of the deposition material 36a measured by the above-described thickness measuring means 37 exceeds a predetermined value. The necessity of cleaning the shutter plate 42 is recognized in advance by the alarm generated by the auxiliary alarm means 39, thus preventing the contamination of the evaporation source 30.

The sensor 50 is mounted within the vacuum chamber 10 to detect the deposition material within the vacuum chamber 10. In this embodiment, the sensor 50 is mounted on the sidewall of the vacuum chamber 10 to measure the amount and the thickness of the deposition material deposited thereon, as shown in FIG. 1. The reason why the sensor 50 is mounted on the sidewall of the vacuum chamber 10 is not to disturb the deposition material being diffused toward the substrate S. A plurality of sensors 50 may be provided in the vacuum chamber 10. If the plurality of sensors 50 are provided, it is preferable that the sensors be arranged on the sidewall of the vacuum chamber 10 spaced apart from each other at regular intervals. For example, the sensor 50 includes twelve crystal sensors arranged parallel to each other on the sidewall of the vacuum chamber 10.

The calculation portion 60 calculates at least one of the thickness of the deposition material deposited on the substrate S, the amount of the deposition material 36 remaining in the evaporation source 30, and the thickness of the deposition material 36a deposited on the evaporation source shutter 40. In this embodiment, although the calculation portion 60 may be mounted on the external sidewall of the vacuum chamber 10 as shown in FIG. 1, or provided separately from the vacuum chamber 10. In any case, the calculation portion 60 is connected with the sensor 50 to receive data on the deposition material measured by the sensor 50. The calculation portion 60 calculates at least one of the thickness of the deposition material deposited on the substrate S, the amount of the deposition material 36 remaining in the evaporation source 30, and the thickness of the deposition material 36a deposited on the evaporation source shutter 40 using the data.

The operation of the calculation portion 60 will be described as follows. The calculation portion 60 calculates the thickness of the deposition material deposited on the substrate S or the thickness of the deposition material 36a deposited on the evaporation source shutter 40 from the thickness of the deposition material deposited on the sensor 50 using a conversion factor. The conversion factor, called a tooling factor, is a ratio value previously calculated so as to predict a value measured at another location from a value measured at a certain location. The conversion factor is determined by the distance from the evaporation source 30 and an evaporation rate of the deposition material in the evaporation source 30. The apparatus 1 for forming the thin film in accordance with the exemplary embodiment diffuses vapor to be deposed on the substrate. Therefore, the density of the vapor and the rate of deposition will differ according to the distance from the evaporation source 30. Accordingly, the distance from the evaporation source is an essential element which determines the conversion factor.

The conversion factor should be calculated considering the evaporation rate of the deposition material. Ideally, the amount of the deposition material deposited on the substrate S or the shutter plate 42 can be expected regardless of the evaporation rate of the deposition material. However, actually, the amount of the deposition material is influenced by the deposition rate. The reason is considered to be that, if the deposition rate is high, the number of molecules of the deposition material existing in the same volume is increased, and thereby the deposition material is not uniformly diffused due to interactions between the deposition material molecules. Therefore, the conversion factors differ for a deposition rate of 1 Å/sec and a deposition rate of 10 Å/sec.

The conversion factor determined by the distance from the evaporation source 30 and the deposition rate is stored in the calculation portion 60. The thickness or the amount of the deposition material deposited on the substrate S and the thickness or the amount of the deposition material 36a deposited on the shutter plate 42 are calculated by multiplying the data on the thickness or the amount of the deposition material measured by the sensor 50 by the conversion factor. With the information on the thus calculated thickness and/or the amount of the deposition material deposited on the substrate S, it is possible to identify the deposition completion time for the substrate S. If the thickness of the deposition material exceeds a predetermined value, it is determined that the process of depositing the thin film on the substrate S is completed, and thereby the thus completed substrate S is discharged to the outside.

Information on the thickness and the amount of the deposition material 36a deposited on the shutter plate 42 allows an operator to identify the cleaning time of the shutter plate 42. That is, if the thickness of the deposition material 36a deposited on the shutter plate 42 exceeds a predetermined constant value, the auxiliary alarm means 39 informs the operator of the same so as to remove the deposition material 36a attached to the shutter plate 42.

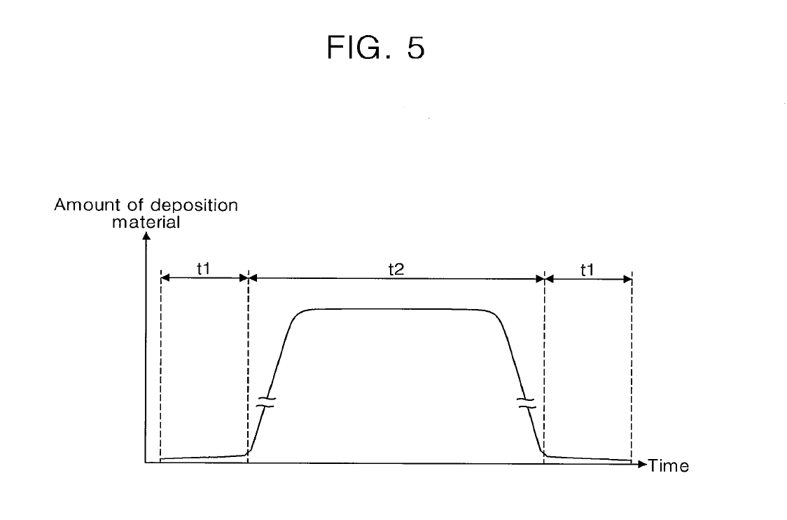

The calculation portion 60 may calculate the amount of the deposition material 36 remaining in the evaporation source 30 based on the amount of the deposition material deposited on the sensor 50. In other words, the calculation portion 60 calculates the amount of the deposition material remaining in the evaporation source 30 using the conversion factor representing the relationship between the amount of the deposition material deposited on the sensor 50 and the total amount of the deposition material consumed in the evaporation source 30. As shown in FIG. 5, the amount of the deposition material deposited on the sensor 50 is a very small amount in a preheating period t1, and is a very large amount in a deposition period t2. If these amounts are summed up, that is, if the area below the graph shown in FIG. 5 is integrated, the amount of the material deposited on the sensor 50 can be obtained. The total amount of the deposition material evaporated in the evaporation source 30 is obtained by multiplying the thus calculated amount by the conversion factor. Like this, if the amount of the deposition material remaining in the evaporation source is obtained, it is possible to prevent the replacement of the evaporation source during the process of depositing the thin film as the deposition material contained in the evaporation source 30 is exhausted. Since it is impossible to replace the evaporation source 30 during the process of depositing the thin film, it is unavoidable that the substrate S in the process of replacing the evaporation source 30 is regarded as a defect.

Accordingly, the apparatus 1 for forming a thin film according to this embodiment is connected to the calculation portion 60, as shown in FIG. 1, and preferably further includes an alarm means 70 generating an alarm if the amount of the deposition material remaining in the evaporation source 30 is less than a predetermined amount. The alarm means 70 has a display function to display an alarm signal and a sound generating function to sound the alarm signal.

Next, a method for forming a thin film will be described as follows.

At first, the substrate S is mounted on the substrate holder 20. At this time, the substrate S is mounted so that the substrate S placed in tension to prevent the center of the substrate S from sagging.

Then, a process of forming a thin film on the substrate S is carried out in three steps in accordance with the present invention. First, a preheating step, in which the evaporation source 30 is preheated before forming the thin film, is performed. Generally, it takes a long time to heat the deposition material to be evaporated. Accordingly, the evaporation source 30 is heated in advance before the deposition process on the substrate S so as to immediately initiate the deposition process as soon as the substrate S is mounted, thus reducing the processing time.

Accordingly, while the substrate is mounted, the preheating process on the evaporation source 30 is performed, or the evaporation source 30 maintains the state preheated at a constant temperature. At this time, the preheating temperature of the evaporation source 30 is preferably a temperature just before the deposition material is evaporated. When the preheating temperature is maintained in the above-described manner, a very small amount, e.g., 0.1 Å/sec, of the deposition material is evaporated. However, in a particular case, a very large amount of the deposition material may be evaporated although the temperature of the evaporation source 30 is maintained at the preheating temperature. If the large amount of deposition material is evaporated, the expensive deposition material is unnecessarily consumed. Accordingly, it is necessary to prevent the waste of the deposition material by lowering the temperature of the evaporation source 30. In this embodiment, the evaporation status within the evaporation source 30 is monitored in real time from the preheating process.

When the evaporation source 30 is preheated, the process of forming a thin film on the substrate S is carried out. In this step, the temperature of the evaporation source 30 is increased to actively evaporate the deposition material. It is possible to control the deposition rate by adjusting the temperature of the evaporation source 30. The evaporation rate may be represented as Å/sec which is the thickness of the thin film formed on the substrate with respect to time. If the deposition rate is too low, long processing time is required, whereas, if it is too high, the deposition material is consumed wastefully.

When the temperature reaches a level enough to sufficiently evaporate the deposition material, the evaporation source shutter 40 is opened so that the deposition material is deposited on the substrate S.

In the preheating step and the deposition step according to this embodiment, the amount and status of the deposition material evaporated in the evaporation source 30 are detected in real time. Using the data on an amount of the evaporation detected, the thickness of the thin film formed on the substrate S, the amount of the deposition material remaining in the evaporation source 30, and/or the thickness of the thin film formed on the evaporation source shutter 40 may be calculated.

Since the method of calculating the thickness of the thin film formed on the substrate S and the amount of the deposition material remaining in the evaporation source is as described above, the detailed description thereof will be omitted.

As a result of the calculation, if the calculated value on the thickness of the deposition material deposited on the substrate exceeds a predetermined value, a deposition completion signal is generated. According to the deposition completion signal, the evaporation source 30 is shut by the shutter plate 42 and the substrate S is ejected. Then, the next substrate is mounted on the substrate holder 20 to perform a subsequent deposition process.

In this way, the total amount of the deposition material consumed in the evaporation source 30 is always monitored even while the deposition process for the substrate S is repeated. If the calculated value on the amount of the deposition material remaining in the evaporation source 30 in accordance with this method is less than a predetermined value, an evaporation source replacement signal is generated. According to the thus generated evaporation source replacement signal, the evaporation source is replaced by a new evaporation source before carrying out the deposition process for the next substrate S.

A process of measuring the thickness of the deposition material deposited on the evaporation source shutter 40 may be further performed. In the process of measuring the thickness of the deposition material deposited on the evaporation source shutter 40, the thickness of the deposition material is measured by irradiating light to the deposition material, by using a moving speed of the evaporation source shutter 40 after applying the same force to the evaporation source shutter 40, or by using torque necessary for moving the evaporation source shutter 40.

If the thickness of the deposition material deposited on the evaporation source shutter 40 exceeds a predetermined value, a deposition material removing signal is generated. According to the thus generated deposition material removing signal, a process of cleaning the lower surface of the shutter plate 42 is performed before the deposition process of the next substrate.

According to the present invention, it is advantageous to accurately predict the replacement time of the evaporation source and the cleaning time of the evaporation source shutter by measuring in real time the thickness of the thin film formed on the substrate and measuring in real time the thickness of the deposition material deposited on the evaporation source shutter.

Further, it is advantageous to prevent unnecessary waste of the deposition material by monitoring in real time the evaporation status which occurs in the evaporation source even during the preheating process.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1.-16. (canceled)

17. A method for forming a thin film, comprising:
mounting a substrate on a substrate holder;
forming a thin film on the substrate by evaporating a deposition material of an evaporation source;
detecting an evaporated amount of the deposition material; and
calculating at least one of the thickness of the thin film formed on the substrate, the amount of the deposition material remaining in the evaporation source, and the thickness of the thin film formed on an evaporation source shutter using data on the evaporated amount detected.

18. The method of claim 17, wherein the forming the thin film on the substrate by evaporating the deposition material of the evaporation source comprises:
maintaining the temperature of the deposition material at a preheating temperature by preheating the evaporation source in a state where an outlet of the evaporation source is closed by the evaporation source shutter;
evaporating the deposition material while maintaining the evaporation temperature by heating the evaporation source; and
depositing the deposition material on the substrate by opening the evaporation source shutter.

19. The method of claim 18, wherein the maintaining the temperature of the deposition material at a preheating temperature by preheating the evaporation source in the state where the outlet of the evaporation source is closed by the evaporation source shutter further comprises monitoring the preheating status by detecting the amount of the deposition material evaporated.

20. The method of claim 19, further comprising lowering the temperature of the evaporation source if the amount of the detected deposition material exceeds a predetermined value.

21. The method of claim 19, wherein the calculating comprises:
creating a conversion factor, by which at least one of the thickness of the deposition material deposited on the substrate, the amount of the deposition material remaining in the evaporation source, and the thickness of the thin film formed on the evaporation source shutter is calculated using the detected data on the evaporation amount; and
calculating at least one of the thickness of the deposition material deposited on the substrate, the amount of the deposition material remaining in the evaporation source, and the thickness of the thin film formed on the evaporation source shutter using the detected data on the evaporation amount and the conversion factor.

22. The method of claim 21, wherein the conversion factor is created by considering a distance from the evaporation source and an evaporation rate of the deposition material in the evaporation source.

23. The method of claim 22, further comprising generating a deposition stop signal if the calculated value on the thickness of the deposition material deposited on the substrate exceeds a predetermined value.

24. The method of claim 22, further comprising generating an evaporation source replacement signal if the calculated value on the amount of the deposition material remaining in the evaporation source is less than a predetermined value.

25. The method of claim 22, further comprising measuring the thickness of the deposition material deposited on the evaporation source shutter.

26. The method of claim 25, wherein the measuring the thickness of the deposition material deposited on the evaporation source shutter comprises measuring the thickness of the deposition material by irradiating light to the deposition material.

27. The method of claim 25, wherein the measuring the thickness of the deposition material deposited on the evaporation source shutter comprises measuring the thickness of the deposition material using a moving speed of the evaporation source shutter after applying the same force to the evaporation source shutter.

28. The method of claim 25, wherein the measuring the thickness of the deposition material deposited on the evaporation source shutter comprises measuring the thickness of the deposition material using a torque value necessary for moving the evaporation source shutter.

29. The method of claim 25, further comprising generating a deposition material removing signal of the deposition material deposited on the evaporation source shutter if the thickness of the deposition material deposited on the evaporation source shutter exceeds a predetermined value.
